(19) United States
(12) Patent Application Publication
(10) Pub. No.: US 2026/0293577 A1
(43) Pub. Date: Sep. 24, 2026

(54) GRINDING SYSTEM AND METHOD OF GRINDING SEMICONDUCTOR STRUCTURE

(71) Applicant: Taiwan Semiconductor Manufacturing Company, Ltd., Hsinchu (TW)

(72) Inventors: Pei-Ching Kuo, Hsinchu City (TW); Chih-Hung Cheng, Hsinchu (TW); Yu-Hsin Liu, Taoyuan City (TW); Chih-Chi Ho, Hsinchu (TW)

(73) Assignee: Taiwan Semiconductor Manufacturing Company, Ltd., Hsinchu (TW)

(21) Appl. No.: 19/083,424

(22) Filed: Mar. 18, 2025

(51) Int. Cl. H01L 21/67; B24B 7/04; H01L 21/683

(52) U.S. Cl. CPC H10P 72/0428; H10P 72/0604; H10P 72/78; B24B 7/04

(57) ABSTRACT

A grinding system includes a chuck and a grinding wheel. The chuck includes a surface that supports a semiconductor substrate. The surface of the chuck includes a first zone and a second zone. The first zone is configured to suck a first zone of the semiconductor substrate with a first suction force. The second zone is configured to suck a second zone of the semiconductor substrate with a second suction force, wherein the second suction force is different from the first suction force. The grinding wheel is configured to grind a surface of the semiconductor substrate.

### BACKGROUND

The continued scaling of semiconductor devices to ever smaller dimensions creates a number of manufacturing challenges. One process related to this trend involves the production of very thin semiconductor wafers used in integrated circuit (IC) fabrication. Some current approaches in the industry use “back-grinding” of semiconductor wafers to reduce their thickness. This practice involves the completion of the front (or “active”) side of a semiconductor wafer, followed by removal of excess substrate from the backside of the wafer.

During the back-grinding process, the wafer is placed on a chuck and a grinding wheel grinds off the excess substrate. There are some systems that grind a wafer in an in-line fashion or sequential/serial, while others grind several wafers concurrently with several respective grinding wheels. Approaches for controlling the back-grinding process typically have involved measurement of related parameters, e.g., measuring the current used to drive the grinding wheel in combination with measuring the revolutions of the grinding wheel spindle.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of a grinding system according to some embodiments.

FIG. 1B is a top view of a chuck of a grinding system of FIG. 1A according to some embodiments.

FIG. 2A to FIG. 2C illustrate a method of grinding a semiconductor structure in accordance with some embodiments. FIG. 3A and FIG. 3B illustrate a cross-sectional view and a top view of a semiconductor structure of FIG. 2A before grinding in accordance with some embodiments, and FIG. 3C illustrate a cross-sectional view of a semiconductor structure of FIG. 2C after grinding in accordance with some embodiments.

FIG. 4 illustrates a semiconductor device including the semiconductor structure of FIG. 3C in accordance with some embodiments.

FIG. 5 illustrates a method of grinding a semiconductor structure in accordance with some embodiments.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

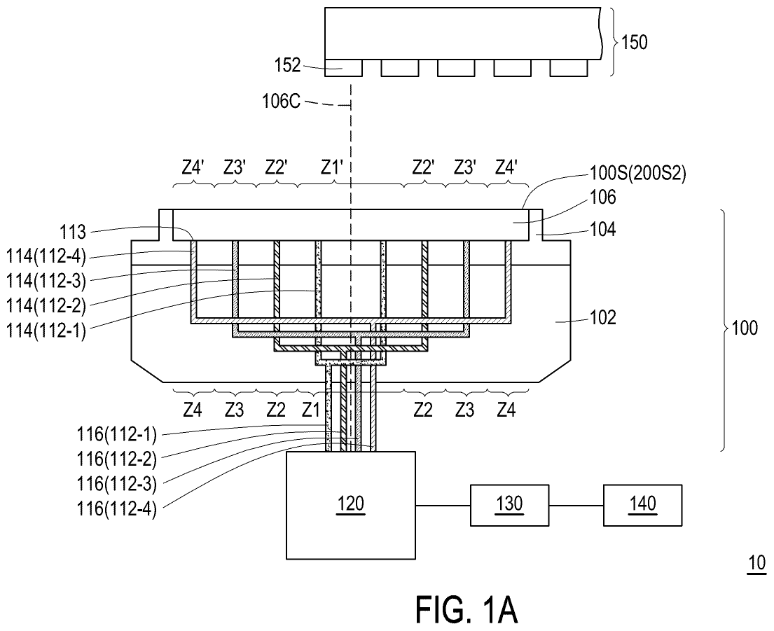

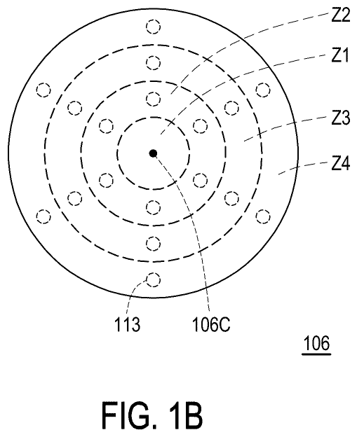

FIG. 1A illustrates a cross-sectional view of a grinding system according to some embodiments. FIG. 1B is a top view of a chuck of a grinding system of FIG. 1A according to some embodiments.

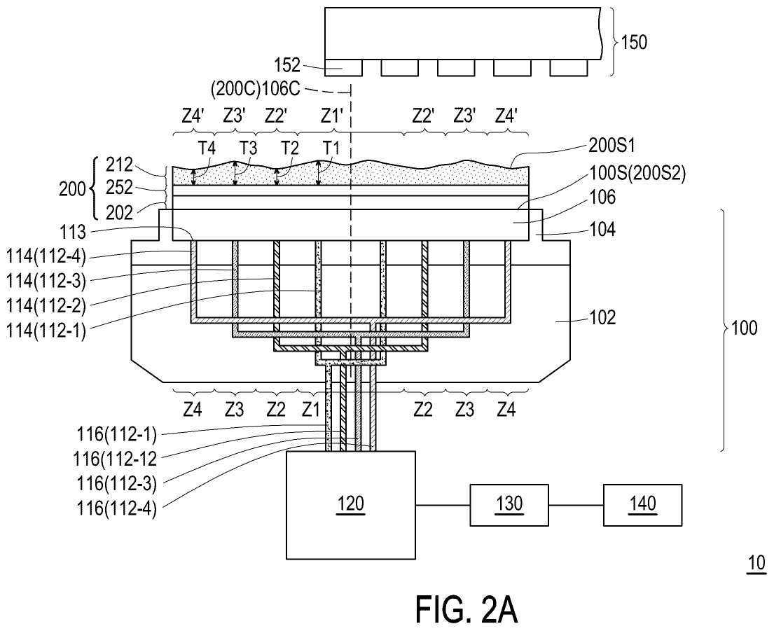

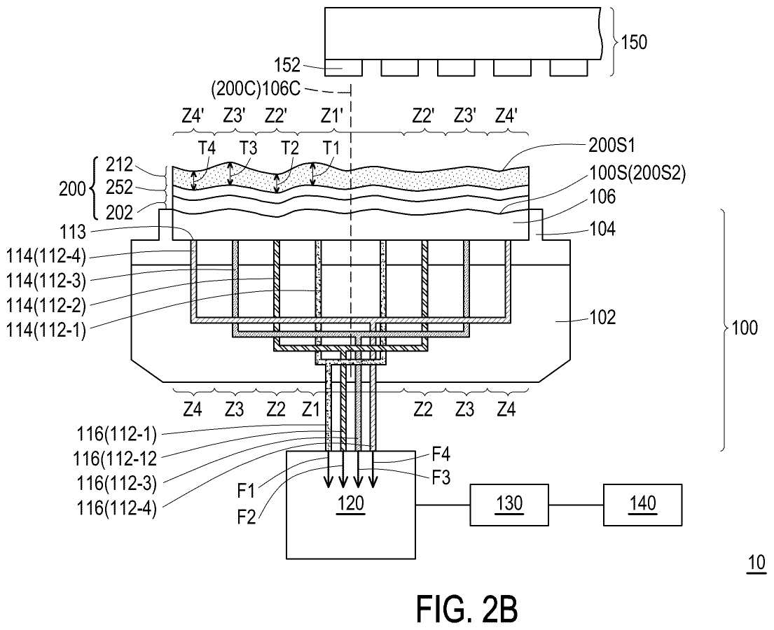

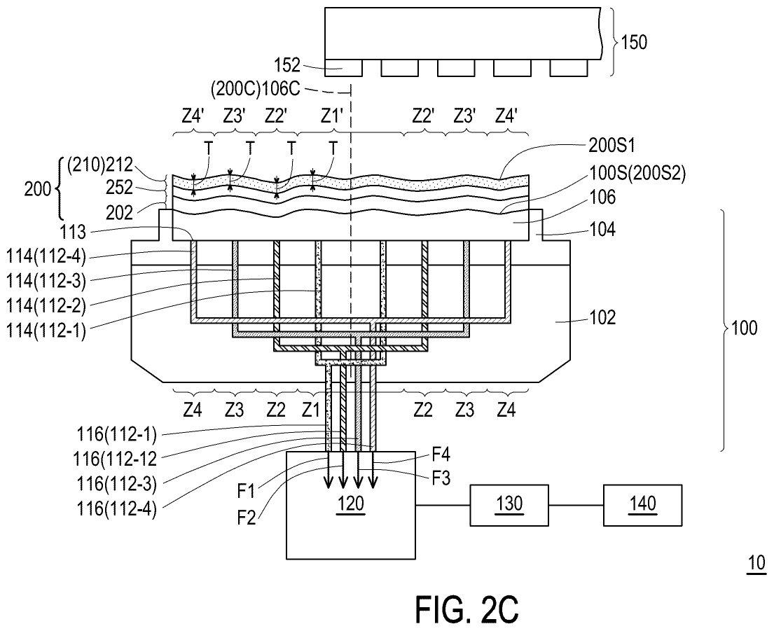

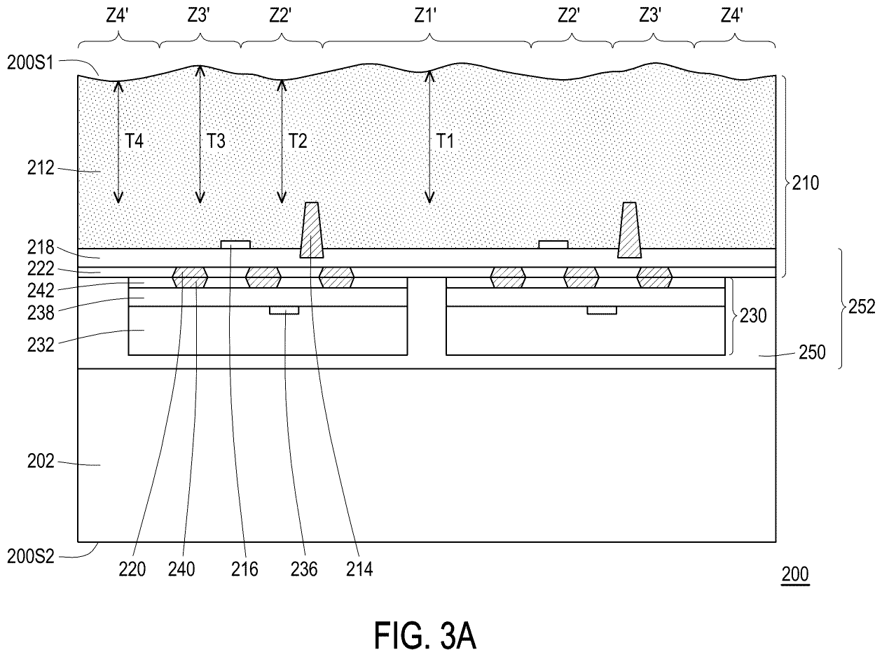

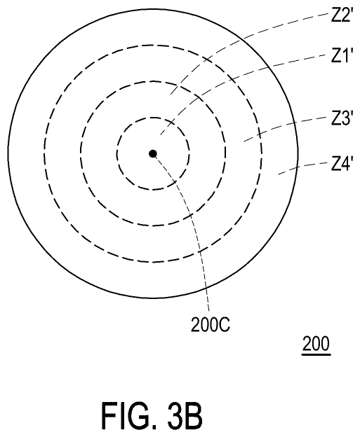

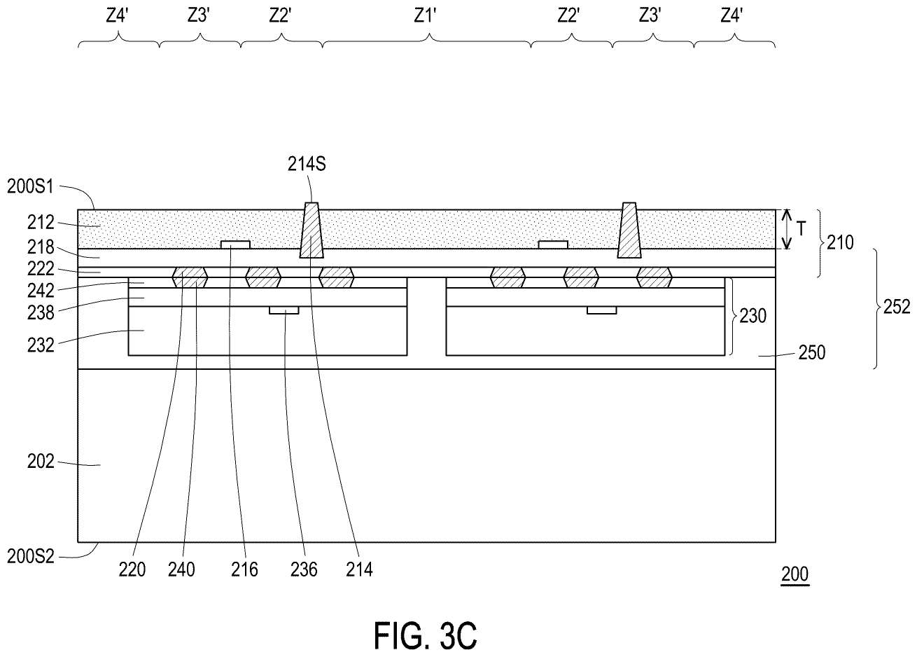

Referring to FIG. 1A, a grinding system 10 is provided. The grinding system 10 is configured for thinning. The grinding system 10 includes a chuck 100 for supporting and a grinding wheel 150 for grinding. The chuck 100 is configured to support a semiconductor structure 200 (as shown in FIG. 2A) thereon. For example, the chuck 100 has a carrying surface 100S to support and secure the semiconductor structure 200 placed thereon. In some embodiments, the chuck 100 includes a base portion 102, a frame portion 104, and a sucking portion 106. The frame portion 104 and the sucking portion 106 are disposed on the base portion 102. For example, the base portion 102 is provided at the bottom of the chuck 100, and the frame portion 104 and the sucking portion 106 are provided at the top of the chuck 100. In some embodiments, the base portion 102 and the frame portion 104 are integrally formed, and the frame portion 104 is an annular partition on the base portion 102. The sucking portion 106 may be in disc form and secured inside the frame portion 104. The sucking portion 106 may be in other forms depending on the design requirements. The chuck 100 is also referred to as a chuck table.

The sucking portion 106 of the chuck 100 may be made of a porous material (e.g., polymer, ceramic, or the like) or other suitable materials. The sucking portion 106 may be also referred to as a porous chuck table, and a top partition of the base portion 102 may be also referred to as a sub-chuck table. In some embodiments, a surface of the sucking portion 106 exposed by the frame portion 104 is used to carry the semiconductor structure 200, such that the surface of the sucking portion 106 is viewed as the carrying surface 100S of the chuck 100. The sucking portion 106 is divided into a plurality of zones Z1, Z2, Z3, Z4. The zones Z1, Z2, Z3, Z4 are arranged from center to edge and surround a center axis 106C of the sucking portion 106. For example, the zone Z1, Z2, Z3, Z4 are ring-shaped and concentric, and a difference between the radiuses of the adjacent zones Z1, Z2, Z3, Z4 is substantially the same. For example, the width of the zone Z2, Z3, Z4 is substantially the same as a radius of the zone Z1. However, the disclosure is not limited thereto. In alternative embodiments, the zones may have other suitable number, shape and/or radiuses.

In some embodiments, the chuck 100 includes a plurality of gas channels 112-1, 112-2, 112-3, 112-4 corresponding to the zones Z1, Z2, Z3, Z4, respectively. The gas channels 112-1, 112-2, 112-3, 112-4 are disposed in the base portion 102 and have openings exposed 113 to the sucking portion 106. In some embodiments, the gas channels 112-1 are physically separated from each other, and thus the gas channels 112-1, 112-2, 112-3, 112-4 may provide gas paths to the sucking portion 106 individually. For example, the gas channel 112-1 provides a gas path to the zone Z1 of the sucking portion 106, the gas channel 112-2 provides a gas path to the zone Z2 of the sucking portion 106, the gas channel 112-3 provides a gas path to the zone Z3 of the sucking portion 106, and the gas channel 112-4 provides a gas path to the zone Z4 of the sucking portion 106. Each gas channel 112-1, 112-2, 112-3, 112-4 may include a plurality of branch channels 114 and a trunk channel 116. The branch channels 114 is vertically and/or horizontally disposed in the base portion 102, and the trunk channel 116 is vertically disposed in the base portion 102, for example. The branch channels 114 are arranged such that different locations of the same zone Z1, Z2, Z3, Z4 of the sucking portion 106 may be sucked with a uniform force by the respective gas channel 112-1, 112-2, 112-3, 112-4. The branch channels 114 may be symmetrically arranged with respect to the center axis 106C of the sucking portion 106. For example, the branch channels 114 are disposed along the periphery of the zone Z1, Z2, Z3, Z4 to surround the center axis 106C. The branch channels 114 respectively have the opening 113 exposed to the bottom of the sucking portion 106 of the chuck 106, and the trunk channel 116 is connected to the branch channels 114. From a top view, as shown in FIG. 1B, the exposed openings 113 of the branch channels 114 may be arranged along a periphery of the sucking portion 106 to surround the center axis 106C. The number of the branch channels 114 and thus the exposed openings 113 of the branch channels 114 may be two or more. The branch channels 114 of the gas channel 112-1, 112-2, 112-3, 112-4 are physically separated, and the trunk channels 116 of the gas channel 112-1, 112-2, 112-3, 112-4 are physically separated, for example. As mentioned above, the sucking portion 106 is made of porous material, and thus the zone Z1, Z2, Z3, Z4 of the sucking portion 106 is liable to communicate with the gas channel 112-1, 112-2, 112-3, 112-4 through the openings 113. It is appreciated that the number of the branch channels may be different depending on the design requirements.

The gas channels 112-1, 112-2, 112-3, 112-4 are connected to a suction device 120 through the trunk channels 116. The suction device 120 may be a vacuum suction device or other suitable suction device. The trunk channel 116 may be disposed between and communicated with the branch channels 114 and the suction device 120. For example, after the semiconductor structure 200 is placed on the chuck 100 and when the chuck 100 is in use, air may be sucked out from inside the sucking portion 106 through the gas channels 112-1, 112-2, 112-3, 112-4 by the suction device 120, such that the semiconductor structure 200 placed on the carrying surface 100S of the chuck 100 may be sucked and secured. In some embodiments, the suction device 120 include a plurality of pumps (not shown), and the pumps are coupled to the gas channels 112-1, 112-2, 112-3, 112-4 respectively. For example, by the pumps, the air in the zones Z1, Z2, Z3, Z4 of the sucking portion 106 is sucked out from inside the sucking portion 106 through the branch channels 114 and the trunk channel 116 of the gas channels 112-1, 112-2, 112-3, 112-4 respectively. In some embodiments, since the gas channels 112-1, 112-2, 112-3, 112-4 are connected to the suction device 120 respectively, the suction device 120 may provide different sucking force to different zones Z1, Z2, Z3, Z4 through the different gas channels 112-1, 112-2, 112-3, 112-4. It should be noted that the vacuum suction device of the chuck 100 serves merely as one of exemplary means to suction and secure the semiconductor structure 200, and other suitable means (e.g., applying mechanical force) of suctioning and securing the semiconductor structure 200 are considered within the scope of other embodiments. It is appreciated that the illustration of the chuck 100 and other components throughout the figures are schematic and some components are omitted. For example, the chuck 100 may be provided with a rotation mechanism (e.g., shaft, motor, controller, or the like (not shown)), thereby allowing rotation around the center axis 106C of the sucking portion 106 as the center.

In some embodiments, the grinding system 10 may include a control device 130. The control device 130 is electrically coupled to the suction device 120, to control the suction forces providing to the zones Z1, Z2, Z3, Z4. In some embodiments, the control device 130 is configured to generate a suction force signal according to a thickness information including mean thicknesses of zone Z1′, Z2′, Z3′, Z4′ of the semiconductor substrate 212 (shown in FIG. 3B) of the semiconductor structure 200. In alternative embodiments, the control device 130 is configured to generate a suction force signal according to a surface planarity information including mean surface planarity of the zone Z1′, Z2′, Z3′, Z4′ of the semiconductor substrate 212 of the semiconductor structure 200. The suction device 120 is configured to provide different suction forces to the respective zones Z1′, Z2′, Z3′, Z4′ of the semiconductor substrate 212 through the zones Z1, Z2, Z3, Z4 of the chuck 100 according to the suction force signal. In other words, the suction force is provided based on the mean thickness and/or the mean surface planarity of the zone Z1′, Z2′, Z3′, Z4′. The thickness information and/or the surface planarity information may be obtained by measuring the mean thicknesses and/or the mean surface planarity of the zone Z1′, Z2′, Z3′, Z4′ of the semiconductor substrate 212 before during and/or after performing the grinding process performing the grinding process.

In some embodiments, the grinding system 10 may optionally include a measurement device 140 to obtain the information such as the thickness information and/or the surface planarity information. For example, the measurement device 140 is configured to measure the mean thicknesses, the mean surface planarity, the like or a combination thereof of the zone Z1′, Z2′, Z3′, Z4′ of the semiconductor substrate 212. The measurement may be performed before during and/or after performing the grinding process performing the grinding process. The measurement device 140 is electrically coupled to the control device 130, to provide the measurement information to the control device 130. The measurement device 140 may include a sensor (not shown) disposed over the semiconductor substrate 212 on the chuck 100, to measure the mean thicknesses and/or the mean surface planarity of the zone Z1′, Z2′, Z3′, Z4′ of the semiconductor substrate 212 by removing the sensor over the zone Z1′, Z2′, Z3′, Z4′. The measurement device may be disposed inside or outside the grinding system 10 depending on where the measurement performs.

The grinding wheel 150 is configured to grind the semiconductor substrate 212. The grinding wheel 150 is disposed over the chuck 100. The grinding wheel 150 applies pressure vertically to a first surface (e.g., backside surface) 200S1 of the semiconductor structure 200 during a back-grinding process that removes excess thickness. For example, the grinding wheel 150 includes a plurality of grinding pads 152 circumferentially disposed on the grinding wheel 150 for grinding or smoothing the semiconductor structure 200. The grinding pads 152 may be applied to the first surface 200S1 of the semiconductor structure 200 for rough grinding and/or polishing. In some embodiments, the chuck 100 and the grinding wheel 150 spin simultaneously in the same direction (i.e., both in a clockwise or counterclockwise direction). In alternative embodiments, the chuck 100 spins opposite to the grinding wheel 150 (e.g., one spins clockwise and the other spins counterclockwise).

FIG. 2A to FIG. 2C illustrate a method of grinding a semiconductor structure in accordance with some embodiments. FIG. 3A and FIG. 3B illustrate a cross-sectional view and a top view of a semiconductor structure of FIG. 2A before grinding in accordance with some embodiments, and FIG. 3C illustrate a cross-sectional view of a semiconductor structure of FIG. 2C after grinding in accordance with some embodiments.

Referring to FIG. 2A, a semiconductor structure 200 is placed onto the chuck 100 of the grinding system 10 of FIG. 1A. The semiconductor structure 200 may be a package structure or other suitable structure including a semiconductor substrate 212 to be thinned. For example, as shown in FIG. 3A, the semiconductor structure 200 includes a carrier 202, a first package component 210, a plurality of second package components 230 and an encapsulant 250. The first package component 210 may be a wafer. The first package component 210 may include a semiconductor substrate 212 to be thinned and a plurality of through vias 214 in the semiconductor substrate 212. The through vias 214 are covered by and embedded in the semiconductor substrate 212. For example, the through vias 214 are embedded in the semiconductor substrate 212 by a first depth. The first package component 210 further includes an active device 216, an interconnect structure 218 and a plurality of bonding pads 220 on the interconnect structure 218. The interconnect structure 218 includes a plurality of dielectric layers (not shown) and a plurality of conductive features (not shown) in the dielectric layers. The bonding pads 220 are electrically connected to the conductive features and disposed in a bonding layer 222. The second package components 230 are disposed between the first package component 210 and the carrier 202. The second package components 230 may be dies. The second package component 230 include a semiconductor substrate 232, an active device 236, an interconnect structure 238 and a plurality of bonding pads 240 on the interconnect structure 238. The interconnect structure 238 includes a plurality of dielectric layers (not shown) and a plurality of conductive features (not shown) in the dielectric layers. The bonding pads 240 are electrically connected to the conductive features and disposed in a bonding layer 242. The encapsulant 250 encapsulates sidewalls of the second package components 230 and is disposed between the first package component 210 and the carrier 202. The bonding pads 240 of the second package components 230 are bonded to the bonding pads 220 of the first package component 210 respectively, such that the second package component 230 are bonded to and electrically connected to the first package component 210. However, the disclosure is not limited thereto. The semiconductor structure 200 may be other suitable structure having a layer to be thinned. For clarify, as shown in FIG. 2A, the layers between the semiconductor substrate 212 and the carrier 202 on the chuck 100 is simplified as layer 252.

The semiconductor structure 200 to be thinned has a first surface 200S1 to be grinded and a second surface 200S2 opposite to the first surface 200S1. The first surface 200S1 is a backside surface, and the second surface 200S2 is a front side surface, for example. The semiconductor substrate 212 of the semiconductor structure 200 is at the first surface 200S1, and the carrier 202 is at the second surface 200S2. The first surface 200S1 faces the grinding wheel 150 and is to be grinded, and the second surface 200S2 is placed onto the sucking portion 106 of the chuck 100 and is to be sucked. In some embodiments, the semiconductor substrate 212 may include different mean thicknesses in different zones, that is, the semiconductor substrate 212 has a total thickness variation (TTV). For example, the semiconductor substrate 212 is divided into a plurality of zones Z1′, Z2′, Z3′, Z4′, and the zones Z1′, Z2′, Z3′, Z4′ may have different mean thicknesses T1, T2, T3, T4. The zones Z1′, Z2′, Z3′, Z4′ are arranged from center to edge and surrounds a center axis 200C of the semiconductor substrate 212. The zones Z1, Z2, Z3, Z4 of the chuck 100 correspond to and overlap with the zone Z1′, Z2′, Z3′, Z4′ respectively, and the center axis 106C of the sucking portion 106 is aligned with the center axis 200C of the semiconductor substrate 212, for example. In some embodiments, the zone Z1′, Z2′, Z3′, Z4′ has the same area and shape as the zones Z1, Z2, Z3, Z4 of the chuck 100 respectively. For example, the zone Z1′, Z2′, Z3′, Z4′ are ring-shaped and concentric, and a difference between the radiuses of the adjacent zones Z1′, Z2′, Z3′, Z4′ may be substantially the same. The width of the zone Z2′, Z3′, Z4′ is substantially the same as a radius of the zone Z1′, for example. However, the disclosure is not limited thereto. In alternative embodiments, the zones may have other suitable number, shape and/or radiuses. Due to the different thicknesses T1, T2, T3, T4 of the zones Z1′, Z2′, Z3′, Z4′, the first surface 200S1 may be a non-planar surface, that is, the first surface 200S1 of some zones is higher than that of other zones. It is noted that the thicknesses and the surface profile/planarity of the semiconductor substrate 212 are merely exemplified and the disclosure is not limited thereto. In some embodiments, the semiconductor substrate 212 has a non-planar surface and different thicknesses across the zones Z2′, Z3′, Z4′. In alternative embodiments, the semiconductor substrate 212 has a substantially coplanar surface and different thicknesses across the zones Z2′, Z3′, Z4′.

The semiconductor structure 200 may be transported from another station to the chuck 100 using a wafer transfer system (not shown). For example, the wafer transfer system includes a holding device (e.g., robot arm). In some embodiments, vacuum lines (not shown) are provided in the holding device, such that the holding device may hold the semiconductor structure 200 thereon through vacuum-absorption. The semiconductor structure 200 may be secured and transported by the wafer transfer system in other suitable means which may stably hold the structure thereon. In some embodiments, the wafer transfer system is first positioned to the semiconductor structure 200 on the stage for transporting. Next, the semiconductor structure 200 is picked up from the stage. For example, the first surface 200S1 of the semiconductor structure 200 is stably held by the holding device, and then the semiconductor structure 200 is transported to the grinding system 10 as shown in FIG. 2A.

Referring to FIG. 2B, suction forces F1, F2, F3, F4 are provided to the zones Z1′, Z2′, Z3′, Z4′ of the semiconductor substrate 212 according to a thickness information. In some embodiments, the mean thicknesses T1, T2, T3, T4 of the zones Z1′, Z2′, Z3′, Z4′ may be measured by the measurement device 140, so as to provide the thickness information. The mean thickness T1, T2, T3, T4 may be an initial thickness of the zones Z1′, Z2′, Z3′, Z4′ before grinding or a real-time thickness of the zones Z1′, Z2′, Z3′, Z4′ during grinding. In other words, the measurement may be performed before the griding process, during the griding process and/or during an interval between two griding processes. The thickness information is then transmitted to the control device 130. The control device 130 may convert the thickness information into a suction force signal, and the suction force signal is then provided to the suction device 120. Accordingly, based on the suction force signal, the suction device 120 provides different suction forces F1, F2, F3, F4 to the zones Z1′, Z2′, Z3′, Z4′ through different gas channels 112-1, 112-2, 112-3, 112-4, respectively.

The suction force signal for the suction forces F1, F2, F3, F4 to the zones Z1′, Z2′, Z3′, Z4′ may be calculated based on the mean thicknesses T1, T2, T3, T4 of the zones Z1′, Z2′, Z3′, Z4′. For example, based on the mean thicknesses T1, T2, T3, T4 of the zones Z1′, Z2′, Z3′, Z4′, a predetermined thickness (e.g., mean thickness of an entire semiconductor substrate 212) and a predetermined suction force may be calculated. The predetermined suction force may be set to remove a determined amount of obtain a thickness exposing the through vias 214, for example. Then, the mean thicknesses T1, T2, T3, T4 of the zones Z1′, Z2′, Z3′, Z4′ may be compared to the predetermined thickness (e.g., mean thickness of an entire semiconductor substrate 212), and the suction forces F1, F2, F3, F4 are respectively calculated from the difference between the mean thicknesses T1, T2, T3, T4 and the predetermined thickness. For example, when the mean thickness T1, T2, T3, T4 of the zone Z1′, Z2′, Z3′, Z4′ is larger than the predetermined thickness, the suction force to the respective zone Z1′, Z2′, Z3′, Z4′ is smaller than the predetermined suction force, so as to increase the vertical distance between the grinding wheel 150. On contrary, when the mean thickness T1, T2, T3, T4 of the zone Z1′, Z2′, Z3′, Z4′ is smaller than the predetermined thickness, the suction force to the respective zone Z1′, Z2′, Z3′, Z4′ is smaller than the predetermined suction force, so as to decrease the vertical distance between the grinding wheel 150. For example, when the mean thickness T1, T2, T3, T4 of the zone Z1′, Z2′, Z3′, Z4′ is larger than the predetermined thickness by 10%, the suction force to the respective zone Z1′, Z2′, Z3′, Z4′ is smaller than the predetermined suction force by 10%. Similarly, when the mean thickness T1, T2, T3, T4 of the zone Z1′, Z2′, Z3′, Z4′ is smaller than the predetermined thickness by 10%, the suction force to the respective zone Z1′, Z2′, Z3′, Z4′ is larger than the predetermined suction force by 10%. In some embodiments, the thickness information is obtained by the measurement device 140 after the semiconductor structure 200 is placed onto the chuck 100. In alternative embodiments, the mean thicknesses of the zones Z1′, Z2′, Z3′, Z4′ of the semiconductor substrate 212 are measured by the measurement device 140 in other station before placing the semiconductor structure 200 onto the chuck 100, to obtain the thickness information. In some embodiments, due to the suction forces F1, F2, F3, F4, the surface (e.g., top surface) profile of the carrier 102, the surface (e.g., top surface) profile of the layer 252 and the first surface 200S1 (e.g., top surface) of the semiconductor substrate 212 are substantially similar to the carrying surface 100S (e.g., top surface) of the chuck 100.

As shown in FIG. 2B, since different suction forces F1, F2, F3, F4 are provided to the zones Z1′, Z2′, Z3′, Z4′ of the semiconductor substrate 212, the first surface 200S1 may be no-coplanar. For example, when the mean thickness T1 of the zone Z1′ is larger than the mean thickness T2 of the zone Z2′, the suction force F1 provided to the zone Z1 of the sucking portion 106 (also the zone Z1′ of the semiconductor substrate 212) is smaller than the suction force F2 provided to the zone Z2 of the sucking portion 106 (also the zone Z2′ of the semiconductor substrate 212). Accordingly, due to the less suction force, the first surface 200S1 of the zone Z1′ of the semiconductor substrate 212 is higher than the first surface 200S1 of the zone Z4′ of the semiconductor substrate 212. Accordingly, the distance between the grinding wheel 150 and the first surface 200S1 of the zone Z1′ of the semiconductor substrate 212 is smaller than the distance between the grinding wheel 150 and the first surface 200S1 of the zone Z2′ of the semiconductor substrate 212, and the contact area between the grinding wheel 150 and the zone Z1′ of the semiconductor substrate 212 is larger than the contact area between the grinding wheel 150 and the zone Z2′ of the semiconductor substrate 212.

The grinding wheel 150 grinds the first surface 200S1 of the semiconductor substrate 212 while the zones Z1′, Z2′, Z3′, Z4′ of the semiconductor substrate 212 are sucked with the suction forces F1, F2, F3, F4 by the suction device 120. In some embodiments, the suction forces F1, F2, F3, F4 may be respectively predetermined and constant during the grinding process. However, the disclosure is not limited thereto. In some embodiments, the measurement device 140 may continuously measure the mean thicknesses of different zones Z1′, Z2′, Z3′, Z4′ of the semiconductor substrate 212, to obtain a real-time thickness information. The control device 130 may continuously generate a real-time suction force signal according to the real-time thickness information to the suction device 120. In such embodiments, the suction device 120 may continuously adjust the suction forces F1, F2, F3, F4 to the zones Z1′, Z2′, Z3′, Z4′ of the semiconductor substrate 212 based on the real-time suction force signal.

In some embodiments, during the griding process, when the zone Z1′, Z2′, Z3′, Z4′ of the semiconductor substrate 212 has a larger thickness T1, T2, T3, T4, the zone Z1′, Z2′, Z3′, Z4′ is sucked with a less sucking force F1, F2, F3 F4. Accordingly, the zone Z1′, Z2′, Z3′, Z4′ of the semiconductor substrate 212 may have a higher surface (i.e., first surface 200S1) and a larger contact area to the grinding pads 152 of the grinding wheel 150, and the zone Z1′, Z2′, Z3′, Z4′ of the semiconductor substrate 212 may be grinded more than others. In other words, the sucking force F1, F2, F3 F4 to the zone Z1′, Z2′, Z3′, Z4′ may be inversely proportional to the mean thickness of the zone Z1′, Z2′, Z3′, Z4′. In such way, during the grinding process, the removal amounts of different zones Z1′, Z2′, Z3′, Z4′ of the semiconductor substrate 212 in a given time may be adjusted, such that the finally remained thickness T of the semiconductor substrate 212 may be uniform as shown in FIG. 2C and FIG. 3C. That is, different zones Z1′, Z2′, Z3′, Z4′ of the semiconductor substrate 212 may have identical thickness T. As shown in FIG. 3C, the through vias 214 are exposed by the semiconductor substrate 212 having the thickness T, that is, surfaces of the through vias 214 are protruded from or substantially coplanar with the first surface 200S1 of the semiconductor structure 200 (e.g., surface of the semiconductor substrate 212). In some embodiments, by respectively controlling the suction forces of different zones of the semiconductor substrate, both the local total thickness variation and the global total thickness variation may be controlled and improved. On contrary, in an embodiment in which the different zones of the semiconductor substrate are provided with the identical sucking force, the finally remained thicknesses of the semiconductor substrate in different zones may be different, and thus the local total thickness variation of the semiconductor substrate remains.

In some embodiments, the suction forces F1, F2, F3, F4 are provided based on the thickness information. However, the disclosure is not limited thereto. As mentioned above, the suction forces F1, F2, F3, F4 may be also provided based on the surface planarity information. In some embodiments in which the semiconductor substrate 212 has a non-coplanar surface due to warpage or the like but has a substantially thickness across the different zones Z1′, Z2′, Z3′, Z4′, the surface of the semiconductor structure 200 may be adjusted to be coplanar by the different suction forces F1, F2, F3, F4. In such embodiments, the surface of different zones Z1′, Z2′, Z3′, Z4′ of the semiconductor substrate 212 are coplanar during the griding process, to remove the semiconductor substrate 212 uniformly across the different zones Z1′, Z2′, Z3′, Z4′. In other words, the different suction forces F1, F2, F3 F4 are provided to adjust the removal amount of the semiconductor substrate 212 across the different zones Z1′, Z2′, Z3′, Z4′ according to the mean thickness and/or the coplanarity of the semiconductor substrate, such that the remained thickness of the semiconductor substrate may be substantially the same.

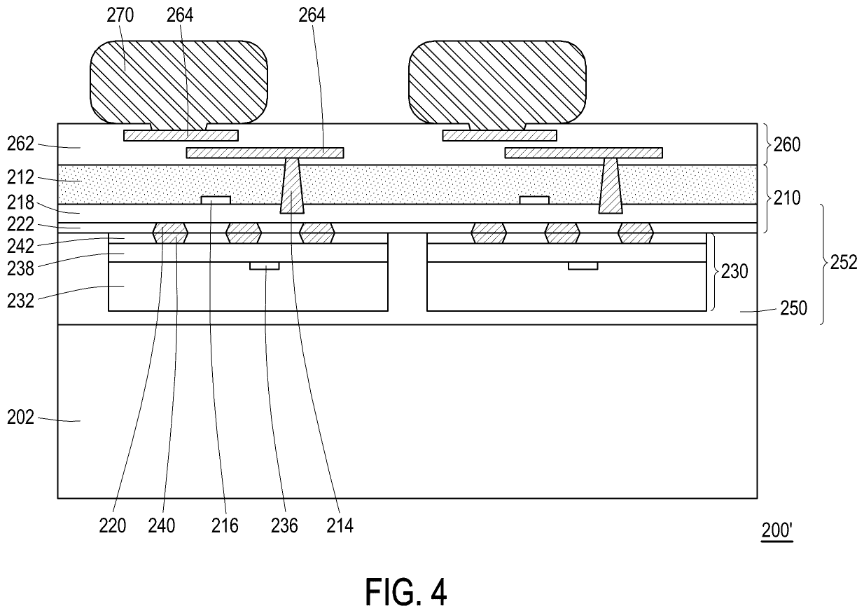

In some embodiments, after the semiconductor structure 200 is thinned by the grinding process, as shown in FIG. 3C and FIG. 4, a redistribution layer (RDL) structure 260 is formed on the first package component 210 and the second package components 230 over the carrier 202. In some embodiments, the redistribution layer structure 260 may include at least one insulating layer 262 and a plurality of conductive features 264 in the insulating layer 262. The redistribution layer structure 260 may be formed by forming an insulating layer, forming a plurality of openings in the insulating layer and forming the conductive features in the insulating layer. The insulating layer 262 may include an organic material such as PBO, polyimide, BCB or the like, an inorganic material such as silicon oxide, silicon nitride or the like. The conductive features 264 may be formed by a damascene process, such as a single damascene process, a dual damascene process, or the like. Then, conductive connectors 270 are formed on the redistribution layer structure, so as to form a package 200′. However, the disclosure is not limited thereto. The grinding system may be applied to thinning any suitable material. In addition, the structure to be thinned may have any suitable configuration and components.

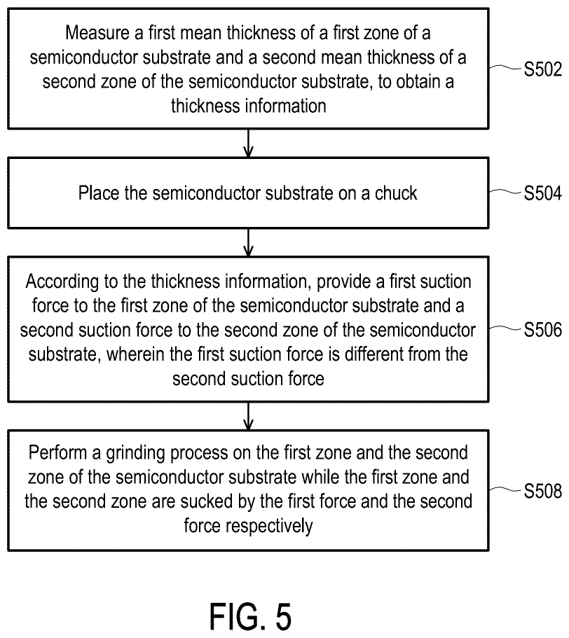

FIG. 5 illustrates a method of grinding a semiconductor structure in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S502, a first mean thickness of a first zone of a semiconductor substrate and a second mean thickness of a second zone of the semiconductor substrate are measured, to obtain a thickness information. As mentioned above, the measurement may be performed before or after placing the semiconductor substrate on the chuck or during the grinding process is performed. FIG. 2A to FIG. 2C illustrate varying views corresponding to some embodiments of act S502.

At act S504, the semiconductor substrate is placed on a chuck. FIG. 2A illustrates a view corresponding to some embodiments of act S504.

At act S506, according to the thickness information, a first suction force is provided to the first zone of the semiconductor substrate and a second suction force is provided to the second zone of the semiconductor substrate, wherein the first suction force is different from the second suction force. FIG. 2B and FIG. 2C illustrate views corresponding to some embodiments of act S506.

At act S508, a grinding process is performed on the first zone and the second zone of the semiconductor substrate while the first zone and the second zone are sucked by the first force and the second force respectively. FIG. 2B and FIG. 2C illustrate views corresponding to some embodiments of act S508.

According to some embodiments of the disclosure, a grinding system includes a chuck and a grinding wheel. The chuck includes a surface that supports a semiconductor substrate. The surface of the chuck includes a first zone and a second zone. The first zone is configured to suck a first zone of the semiconductor substrate with a first suction force. The second zone is configured to suck a second zone of the semiconductor substrate with a second suction force, wherein the second suction force is different from the first suction force. The grinding wheel is configured to grind a surface of the semiconductor substrate.

According to some embodiments of the disclosure, a grinding system includes a chuck and a grinding wheel. The chuck is configured to support a semiconductor substrate thereon. The control device is configured to generate a suction force signal according to a thickness information including a first mean thickness of a first zone of the semiconductor substrate and a second mean thickness of a second zone of the semiconductor substrate, wherein the first mean thickness is different from the second mean thickness. The suction device is electrically coupled to the control device, configured to provide a first suction force to the first zone of the semiconductor substrate and a second suction force to the second zone of the semiconductor substrate according to the suction force signal, wherein the first suction force is different from the second suction force. The grinding wheel is configured to reduce a thickness of the first zone and the second zone of the semiconductor substrate.

According to some embodiments of the disclosure, a method of grinding a semiconductor structure includes the following steps. A first mean thickness of a first zone of a semiconductor substrate and a second mean thickness of a second zone of the semiconductor substrate are measured, to obtain a thickness information. The semiconductor substrate is placed on a chuck. According to the thickness information, a first suction force is provided to the first zone of the semiconductor substrate and a second suction force is provided to the second zone of the semiconductor substrate, wherein the first suction force is different from the second suction force. A grinding process is performed on the first zone and the second zone of the semiconductor substrate while the first zone and the second zone are sucked by the first force and the second force respectively.

The foregoing outlines features of several embodiments such that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A grinding system, comprising:
a chuck, comprising a surface that supports a semiconductor substrate, the surface of the chuck comprising:
a first zone, configured to suck a first zone of the semiconductor substrate with a first suction force; and
a second zone, configured to suck a second zone of the semiconductor substrate with a second suction force, wherein the second suction force is different from the first suction force; and
a grinding wheel, configured to grind a surface of the semiconductor substrate.

2. The grinding system of claim 1, wherein the first zone and the second zone are respectively ring-shaped and concentric.

3. The grinding system of claim 1, further comprising:
a first gas channel exposed to the first zone; and
a second gas channel exposed to the second zone, wherein the first gas channel is physically separated from the second gas channel.

4. The grinding system of claim 3, wherein
the first gas channel comprises:
a plurality of first branch gas channels exposed to the first zone; and
a first main gas channel in communication with the first branch gas channels;
the second gas channel comprises:
a plurality of second branch gas channels exposed to the second zone; and
a second main gas channel in communication with the second branch gas channels.

5. The grinding system of claim 4, wherein the first branch gas channels are disposed at opposite sides of a center axis of the surface of the chuck, and the second branch gas channels are disposed at opposite sides of the center axis of the surface of the chuck.

6. The grinding system of claim 5, wherein a distance between the first branch gas channels and the center axis of the surface of the chuck is different from a distance between the second branch gas channels and the center axis of the surface of the chuck.

7. The grinding system of claim 3, further comprising a suction device in communication with the first gas channel and the second gas channel respectively.

8. A grinding system, comprising:
a chuck, configured to support a semiconductor substrate thereon;
a control device, configured to generate a suction force signal according to a thickness information including a first mean thickness of a first zone of the semiconductor substrate and a second mean thickness of a second zone of the semiconductor substrate, wherein the first mean thickness is different from the second mean thickness;
a suction device, electrically coupled to the control device, configured to provide a first suction force to the first zone of the semiconductor substrate and a second suction force to the second zone of the semiconductor substrate according to the suction force signal, wherein the first suction force is different from the second suction force; and
a grinding wheel, configured to reduce a thickness of the first zone and the second zone of the semiconductor substrate.

9. The grinding system of claim 8, wherein the chuck comprises a first zone configured to suck the first zone of the semiconductor substrate and a second zone configured to suck the second zone of the semiconductor substrate.

10. The grinding system of claim 9, wherein the chuck comprises:
a first gas channel exposed to the first zone of the chuck and in communicated with the suction device; and
a second gas channel exposed to the second zone of the chuck and in communicated with the suction device, wherein the first gas channel is physically separated from the second gas channel.

11. The grinding system of claim 10, wherein
the first gas channel comprises:
a plurality of first branch gas channels exposed to the first zone of the chuck; and
a first main gas channel in communication with the first branch gas channels and the suction device;
the second gas channel comprises:
a plurality of second branch gas channels exposed to the second zone of the chuck; and
a second main gas channel in communication with the second branch gas channels and the suction device.

12. The grinding system of claim 8, wherein the suction device is a vacuum suction device.

13. The grinding system of claim 8, further comprising a detection device, configured to measure the first mean thickness of the first zone of the semiconductor substrate and the second mean thickness of the second zone of the semiconductor substrate to generate the thickness information.

14. A method of grinding a semiconductor structure, comprising:
measuring a first mean thickness of a first zone of a semiconductor substrate and a second mean thickness of a second zone of the semiconductor substrate, to obtain a thickness information;
placing the semiconductor substrate on a chuck;
according to the thickness information, providing a first suction force to the first zone of the semiconductor substrate and a second suction force to the second zone of the semiconductor substrate, wherein the first suction force is different from the second suction force; and
performing a grinding process on the first zone and the second zone of the semiconductor substrate while the first zone and the second zone are sucked by the first force and the second force respectively.

15. The method of claim 14, wherein the semiconductor structure further comprises a carrier between the semiconductor substrate and the chuck.

16. The method of claim 14, wherein the first zone of the semiconductor substrate has a first surface subjected to the grinding process and the second zone of the semiconductor substrate has a second surface subjected to the grinding process, and the first surface is non-coplanar with the second surface.

17. The method of claim 14, wherein the first force is smaller than the second force when the first mean thickness is larger than the second mean thickness.

18. The method of claim 14, wherein the thickness information is obtained before performing the grinding process.

19. The method of claim 14, wherein the thickness information is obtained while performing the grinding process.

20. The method of claim 14, wherein a first remaining thickness of the first zone is substantially equal to a second remaining thickness of the second zone after performing the grinding process.
